(19) United States
(12) Patent Application Publication
(10) Pub. No.: US 2026/0052697 A1
(43) Pub. Date: Feb. 19, 2026

(54) SEMICONDUCTOR DEVICE AND MEMORY DEVICE INCLUDING THE SAME

(71) Applicant: Samsung Electronics Co., Ltd., Suwon-si (KR)

(72) Inventors: Jungkyun KIM, Suwon-si (KR); Sangwook KIM, Suwon-si (KR); Jeeeun YANG, Suwon-si (KR); Narae HAN, Suwon-si (KR); Sijung YOO, Suwon-si (KR); Sanghyun JO, Suwon-si (KR)

(73) Assignee: Samsung Electronics Co., Ltd., Suwon-si (KR)

(21) Appl. No.: 19/237,667

(22) Filed: Jun. 13, 2025

(30) Foreign Application Priority Data
Aug. 16, 2024 (KR) 10-2024-0110012

(51) Int. Cl. H10B 51/30; H10B 51/20

(52) U.S. Cl. CPC H10B 51/30; H10B 51/20

(57) ABSTRACT

A semiconductor device includes a channel layer including an oxide semiconductor material including indium (In), gallium (Ga), or zinc (Zn), a ferroelectric layer on the channel layer, and a gate electrode on the ferroelectric layer. A composition ratio of In:Ga:Zn in the oxide semiconductor material is 1:1.3-1.7:1.3-1.7 in atomic percent (at %).

### CROSS-REFERENCE TO RELATED APPLICATION

This application is based on and claims priority under 35 U.S.C. § 119 to Korean Patent Application No. 10-2024-0110012, filed on Aug. 16, 2024, in the Korean Intellectual Property Office, the disclosure of which is incorporated by reference herein in its entirety.

### BACKGROUND

### 1. Field

The disclosure relates to a semiconductor device and a memory device including the same.

### 2. Description of the Related Art

Ferroelectric field effect transistors (FeFETs) refer to memories having a ferroelectric gate insulating layer and oxide-channel FeFETs refer to FeFETs having an oxide semiconductor channel such as InGaZnO.

Oxide-channel FeFETs are non-volatile memory devices with ferroelectricity and low channel leakage current characteristics. Oxide-channel FeFETs have the advantage of being able to be implemented as low-power, high-speed devices by storing information through spontaneous polarization, but have the limitation of exhibiting characteristics of a low memory window.

### SUMMARY

Provided are a semiconductor device having a relatively high memory window and a memory device including the semiconductor device.

Additional aspects will be set forth in part in the description which follows and, in part, will be apparent from the description, or may be learned by practice of the presented embodiments of the disclosure.

According to an aspect of the disclosure, provided is a semiconductor device including a channel layer including an oxide semiconductor material including indium (In), gallium (Ga), and zinc (Zn); a ferroelectric layer on the channel layer, and a gate electrode on the ferroelectric layer such that the ferroelectric layer insulates the channel layer from the gate electrode, wherein a composition ratio of In:Ga:Zn in the oxide semiconductor material is 1:1.3-1.7:1.3-1.7 in atomic percent (at %).

The gate electrode may indium tin oxide (ITO), molybdenum (Mo), tungsten (W), ruthenium (Ru), or a combination thereof.

The ferroelectric layer may include a non-centrosymmetric crystal structure.

The ferroelectric layer may include an orthorhombic crystal structure at a portion in contact with the gate electrode.

The ferroelectric layer may include at least one of hafnium oxide, zirconium oxide, or hafnium zirconium oxide (HfₓZr₁₋ₓO₂ (0<x<1)).

The semiconductor device may further include a source electrode and a drain electrode spaced apart from each other with the channel layer therebetween.

The semiconductor device may further include at least one of a first contact layer between the source electrode and the channel layer or a second contact layer between the drain electrode and the channel layer.

The first contact layer and the second contact layer may each include an In-containing oxide.

Each of the first contact layer and the second contact layer may include ITO or indium oxide.

The composition ratio of In:Ga:Zn in the oxide semiconductor material may be 2:3:3 in at %.

According to at least one embodiment, an electronic device may include the semiconductor device described above.

According to another aspect of the disclosure, provided is a memory device including a plurality of memory cells disposed vertically on a substrate, wherein each of the plurality of memory cells includes a ferroelectric layer on a gate electrode, the gate electrode extending in a direction perpendicular to the substrate, and a channel layer on the ferroelectric layer such that the ferroelectric layer insulates the channel layer from the gate electrode, the channel layer including an oxide semiconductor material including In, Ga, and Zn, wherein a composition ratio of In:Ga:Zn in the oxide semiconductor material is 1:1.3-1.7:1.3-1.7 in at %.

The gate electrode may ITO, Mo, W, Ru, or a combination thereof.

The ferroelectric layer may include at least one of hafnium oxide, zirconium oxide, or hafnium zirconium oxide (HfₓZr₁₋ₓO₂ (0<x<1)).

The memory device may further include a source electrode and a drain electrode on respective sides of each of the plurality of memory cells.

The gate electrode may be shared by the plurality of memory cells.

The composition ratio of In:Ga:Zn in the oxide semiconductor material may be 2:3:3 in at %.

According to another aspect of the disclosure, provided is a method of manufacturing a semiconductor device, the method including providing a channel layer, providing a ferroelectric layer on the channel layer, and providing a gate electrode on the ferroelectric layer, wherein the channel layer includes an oxide semiconductor material including In, Ga, and Zn and a composition ratio of In:Ga:Zn in the oxide semiconductor material is 1:1.3-1.7:1.3-1.7 in at %.

The ferroelectric layer may include at least one of hafnium oxide, zirconium oxide, or hafnium zirconium oxide (HfₓZr₁₋ₓO₂ (0<x<1)).

The channel layer and the ferroelectric layer may be prepared through an atomic layer deposition process.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a semiconductor device according to at least one embodiment;

FIGS. 2A and 2B are graphs showing the results of endurance testing (ET) characteristics of a semiconductor device according to at least one embodiment;

FIG. 3 is a graph showing a memory window of a semiconductor device according to at least one embodiment;

FIG. 4 is a graph showing a memory window of a semiconductor device according to at least one embodiment;

FIGS. 5A and 5B are graphs showing the ferroelectricity of a semiconductor device according to at least one embodiment;

FIG. 6 is a transmission electron microscope (TEM) image of a semiconductor device according to at least one embodiment;

FIGS. 7A to 7E are diagrams illustrating a method of manufacturing a semiconductor device, according to at least one embodiment;

FIG. 8 is a perspective view schematically illustrating a semiconductor device according to another embodiment;

FIG. 9 is a cross-sectional view taken along line I-I′ of FIG. 8;

FIG. 10 is a perspective view illustrating a memory device according to at least one embodiment;

FIG. 11 is a plan view of the memory device illustrated in FIG. 10;

FIG. 12 is a cross-sectional view taken along line II-II′ of FIG. 11;

FIG. 13 is a conceptual diagram schematically illustrating a device architecture applicable to an electronic device, according to embodiments;

FIG. 14 is a block diagram of a memory system according to at least one embodiment;

FIG. 15 is a schematic circuit diagram of a neural network device according to at least one embodiment; and

FIG. 16 is a block diagram schematically illustrating an example of a configuration of an electronic device including a neural network device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and a memory device including the same, according to various embodiments, will be described in detail with reference to the accompanying drawings. In the following drawings, the same reference numerals denote the same elements, and the size of each element in the drawings may be exaggerated for clarity and convenience of explanation. In addition, embodiments described herein are merely examples, and various modifications may be made thereto from these embodiments.

Hereinafter, the terms “above” or “on” may include not only those that are directly on in a contact manner, but also those that are above in a non-contact manner. Additionally, it will be understood that spatially relative terms, such as “above,” “top,” etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

Also, in the specification, the functional elements, including those including terms such as “unit,” “block,” “ . . . controller,” etc. denote units that process at least one function or operation, and may be realized by and/or include processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. Connecting lines or connecting members illustrated in the drawings are intended to represent exemplary functional relationships and/or physical or logical connections between the various elements. It should be noted that many alternative or additional functional relationships, physical connections or logical connections may be present in a practical device.

Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, the use of all illustrations or illustrative terms in the embodiments is simply to describe the technical ideas in detail, and the scope of the inventive concept is not limited by the illustrations or illustrative terms unless they are limited by claims.

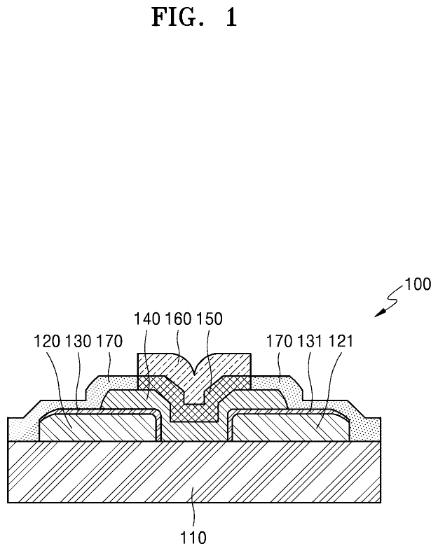

FIG. 1 is a diagram illustrating a semiconductor device 100 according to at least one embodiment.

Referring to FIG. 1, the semiconductor device 100 may include a substrate 110, a pair of source/drain electrodes (a source electrode 120 and a drain electrode 121) on the substrate 110, a channel layer 140 between the source electrode 120 and the drain electrode 121, a ferroelectric layer 150 on the channel layer 140, and a gate electrode 160 on the ferroelectric layer 150.

The substrate 110 may include a semiconductor material, for example, an elemental semiconductor (e.g., silicon (Si), germanium (Ge), silicon germanium (SiGe), etc.) and/or a compound semiconductor (e.g., Group III-V semiconductor). The substrate 110 may be, for example, a silicon substrate having silicon oxide formed on a surface thereof. However, the disclosure is not limited thereto. In at least some embodiments, a buffer layer (not illustrated) may be further provided between the substrate 110 and the channel layer 140. The buffer layer may include, for example, SiO₂. However, the disclosure is not limited thereto.

The source electrode 120 and the drain electrode 121 may be spaced apart from each other by a predefined interval on the substrate 110. The source electrode 120 and the drain electrode 121 may be provided on opposite sides of the gate electrode 160 with respect to the channel layer 140.

Each of the source electrode 120 and the drain electrode 121 may include a conductive material, including, e.g., a zero-band gap material. For example, the source electrode 120 and the drain electrode 121 may include a conductive material including at least one of tungsten (W), cobalt (Co), nickel (Ni), iron (Fc), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sb), vanadium (V), ruthenium (Ru), platinum (Pt), zinc (Zn), magnesium (Mg), a combination thereof, and/or a conductive nitride thereof.

The channel layer 140 may extend between the source electrode 120 and the drain electrode 121 and up to a portion above the source electrode 120 and the drain electrode 121. The channel layer 140 may include an oxide semiconductor material. For example, the channel layer 140 may include an oxide semiconductor material including indium (In), gallium (Ga), and/or zinc (Zn). The channel layer 140 may include indium-gallium-zinc oxide (IGZO).

A composition ratio of In:Ga:Zn in the oxide semiconductor material may be 1:1.3-1.7:1.3-1.7 in atomic percent (at %). For example, the composition ratio of In:Ga:Zn in the oxide semiconductor material may be, for example, 2:3:3 in at %.

The ferroelectric layer 150 may include a ferroelectric material. The ferroelectric material is a material that has ferroelectricity to maintain spontaneous polarization by aligning internal electric dipole moments even when no external electric field is applied thereto. A threshold voltage of the semiconductor device 100 according to at least one embodiment may be changed by changing a polarization direction of the ferroelectric layer 150, for example, according to a direction from the gate electrode 160 toward the channel layer 140, or conversely, a direction from the channel layer 140 toward the gate electrode 160.

The ferroelectric layer 150 may include at least one of hafnium oxide, zirconium oxide, or hafnium zirconium oxide (HfₓZr₁₋ₓO₂ (0<x<1)) and have a ferroelectric phase (e.g., a crystal structure lacking an inversion center (e.g., is non-centrosymmetric)) in the largest proportion among all crystal phases and/or as a dominant phase. The ferroelectric layer 150 may have an orthorhombic structure. The ferroelectric layer 150 may have an orthorhombic structure at a portion in contact with the gate electrode 160.

The gate electrode 160 may include a conductive material. The gate electrode 160 may include, for example, metal, metal nitride, metal oxide, polysilicon, and/or the like. As a specific example, the gate electrode 160 may include at least one of W, TiN, TaN, WN, NbN, Mo, Ru, Ir, RuO, IrO, and/or highly doped polysilicon. The gate electrode 160 may include metal carbide or a two-dimensional conductive material. The gate electrode 160 may include, for example, indium tin oxide (ITO), Mo, W, Ru, and/or a combination thereof.

When necessary, the semiconductor device 100 may optionally further include a first contact layer 130 between the source electrode 120 and the channel layer 140 and a second contact layer 131 between the drain electrode 121 and the channel layer 140. Each of the first contact layer 130 and the second contact layer 131 may be configured to lower the contact resistance between the source electrode 120 and the channel layer 140 and the contact resistance between the drain electrode 121 and the channel layer 140.

Each of the first contact layer 130 and the second contact layer 131 may include an In-containing oxide. Each of the first contact layer 130 and the second contact layer 131 may include, for example, ITO or indium oxide.

The semiconductor device 100 may further include a protective layer 170 surrounding the source electrode 120, the drain electrode 121, the channel layer 140, and the ferroelectric layer 150. The protective layer 170 may include an insulator, such as silicon oxide or silicon nitride.

The semiconductor device 100 according to at least one embodiment may correspond to each memory cell constituting a memory device. The semiconductor device 100 according to at least one embodiment may be referred to as a ferroelectric field effect transistor. The semiconductor device 100 according to at least one embodiment may use an oxide semiconductor material as the channel layer 140. By controlling the composition ratio of In:Ga:Zn in the oxide semiconductor material, the memory window, which is the difference between two different threshold voltages of the semiconductor device 100, may be increased to about 3.0 V.

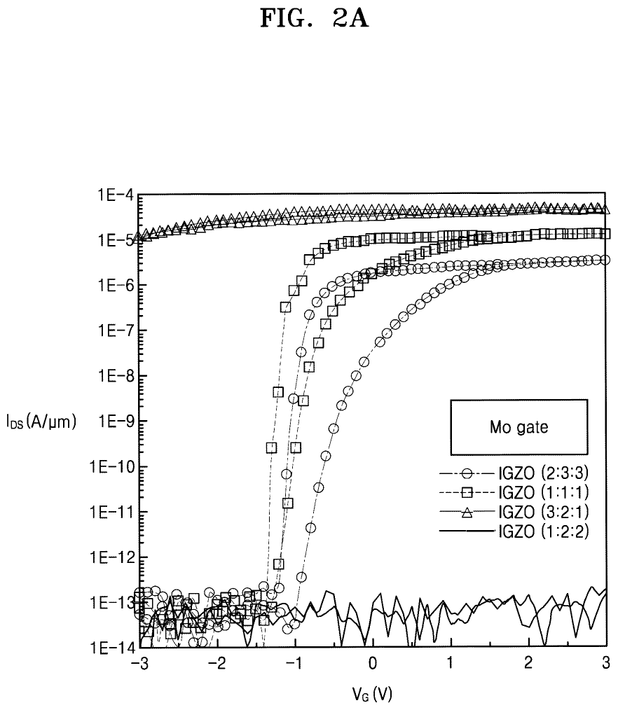

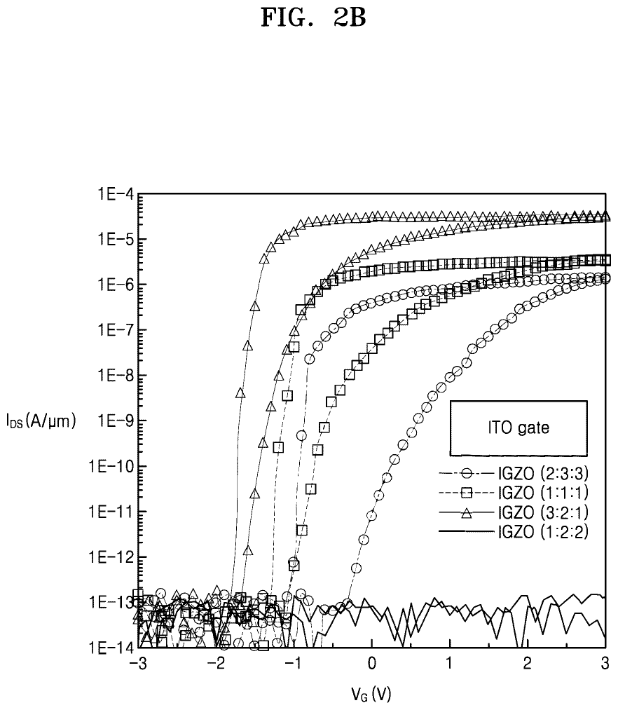

FIGS. 2A and 2B are graphs showing the results of endurance testing (ET) characteristics of the semiconductor device according to at least one embodiment.

FIG. 2A illustrates a current flowing through a channel layer when a constant gate voltage is applied by changing a composition ratio of In:Ga:Zn in an oxide semiconductor material forming a channel layer in a semiconductor device in which Mo is used as a gate electrode, and FIG. 2B illustrates a current flowing through a channel layer when a constant gate voltage is applied by changing a composition ratio of In:Ga:Zn in an oxide semiconductor material forming a channel layer in a semiconductor device in which ITO is used as a gate electrode.

Referring to FIGS. 2A and 2B, the memory window is not detected in a semiconductor device in which Mo is used as a gate electrode and a composition ratio of In:Ga:Zn in an oxide semiconductor material forming a channel layer is 3:2:1 in at % and a semiconductor device in which a composition ratio of In:Ga:Zn is 1:2:2 in at %.

In addition, the memory window is the largest in a semiconductor device in which ITO is used as a gate electrode and a composition ratio of In:Ga:Zn in an oxide semiconductor material forming a channel layer is 2:3:3 in at %.

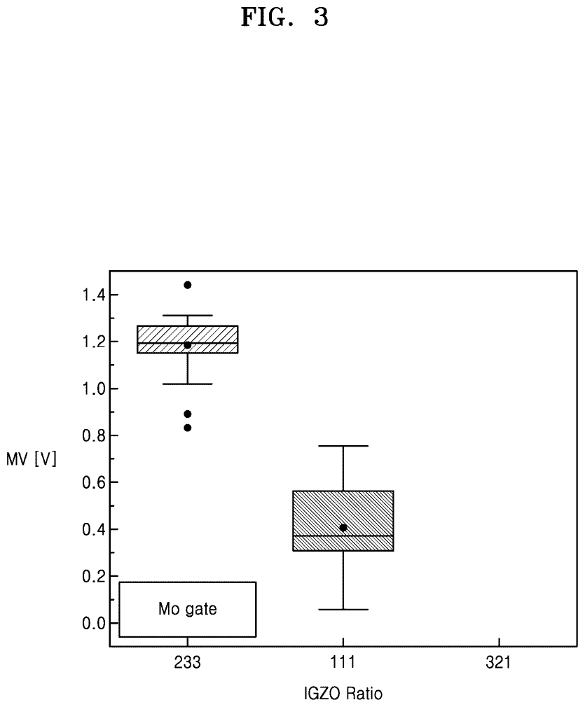

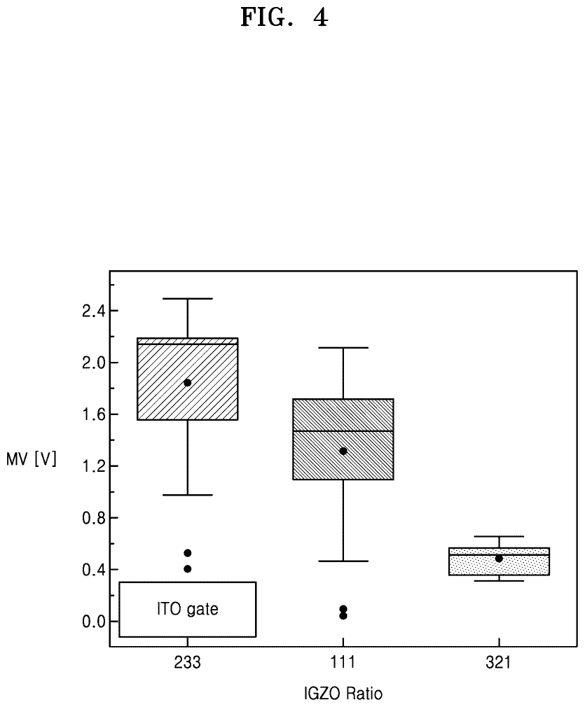

FIGS. 3 and 4 are graphs showing memory windows of semiconductor devices according to at least one embodiment.

The memory windows of the semiconductor devices in FIGS. 3 and 4 are values measured from 25 dies of a wafer. The memory windows were measured through the difference between a program voltage and an erase voltage.

Referring to FIGS. 3 and 4, the memory window is larger in a semiconductor device in which ITO is used as a gate electrode than in a semiconductor device in which Mo is used as a gate electrode and that the memory window is larger in a semiconductor device in which a composition ratio of In:Ga:Zn in an oxide semiconductor material forming a channel layer is 2:3:3 in at %.

In addition, the memory window is the largest in a semiconductor device in which ITO is used as a gate electrode and a composition ratio of In:Ga:Zn in an oxide semiconductor material forming a channel layer is 2:3:3 in at %.

On the other hand, when a gate voltage of ±4 V was applied to a semiconductor device in which ITO was used as a gate electrode and a composition ratio of In:Ga:Zn in an oxide semiconductor material forming a channel layer is 2:3:3 in at %, a memory window showed a high value of 3.0 V. At this time, an overlapping region of the gate electrode, the channel layer, and the ferroelectric layer has a scale of 2 μm in length and 0.5 μm in width.

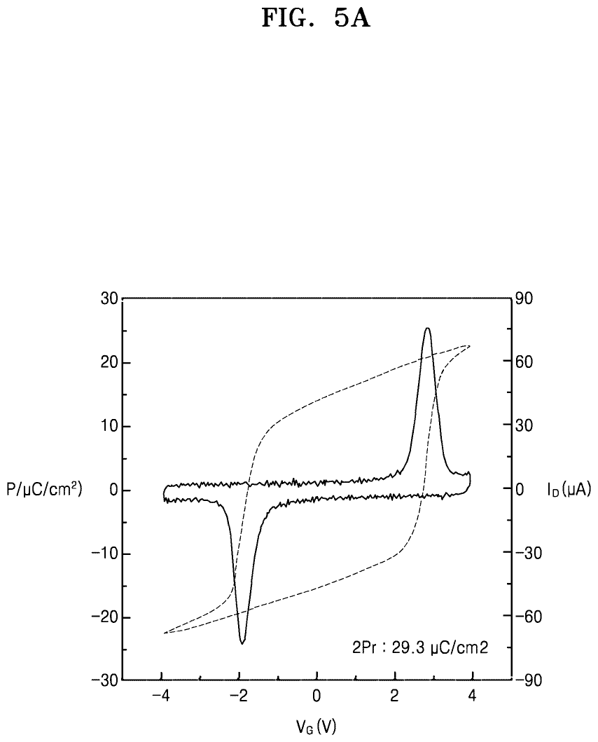

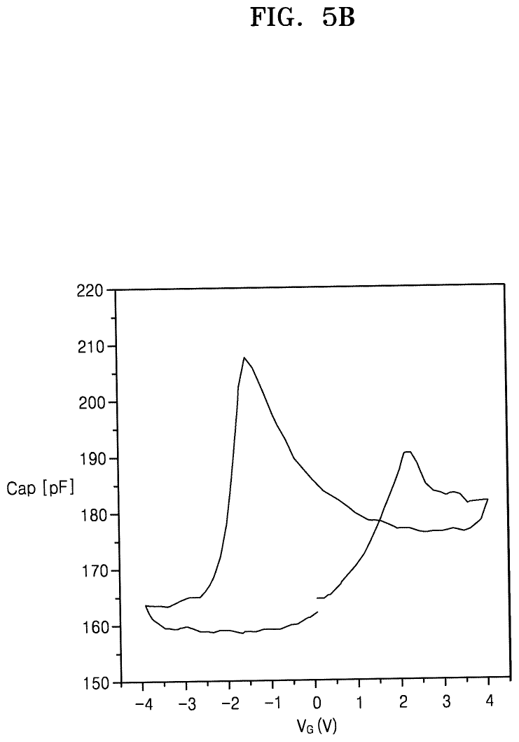

FIGS. 5A and 5B are graphs showing characteristics of a semiconductor device according to at least one embodiment.

FIG. 5A shows power of a semiconductor device when a constant gate voltage is applied to a semiconductor device in which ITO is used as a gate electrode and a composition ratio of In:Ga:Zn in an oxide semiconductor material forming a channel layer is 2:3:3 in at %.

Referring to FIG. 5A, a 2Pr value of the semiconductor device according to at least one embodiment has 29.3 microcoulomb per square centimeter (μC/cm²). Accordingly, the semiconductor device according to at least one embodiment is confirmed to exhibit ferroelectric characteristics.

FIG. 5B shows a capacitance of a semiconductor device when a constant gate voltage is applied to a semiconductor device in which ITO is used as a gate electrode and a composition ratio of In:Ga:Zn in an oxide semiconductor material forming a channel layer is 2:3:3 in at %.

Referring to FIG. 5B, a current-voltage (C-V) curve of the semiconductor device according to at least one embodiment exhibits a butterfly shape. Accordingly, the semiconductor device according to at least one embodiment is confirmed to exhibit ferroelectric characteristics.

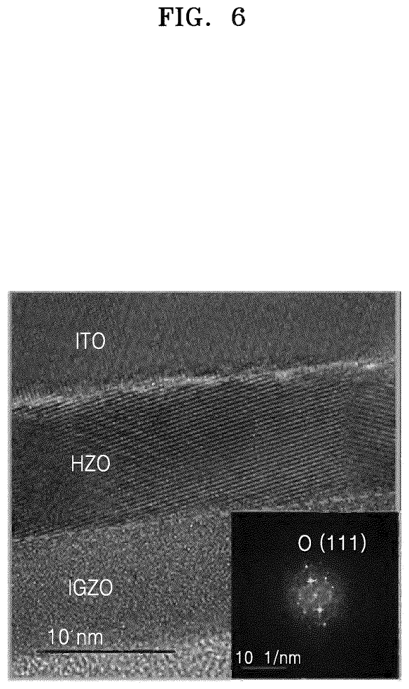

FIG. 6 is a transmission electron microscope (TEM) image of a semiconductor device according to at least one embodiment.

Referring to FIG. 6, a (111) crystal orientation arrangement of an orthorhombic crystal structure may be found in a ferroelectric layer denoted by HZO through a diffraction pattern. In addition, the ferroelectric layer denoted by HZO is confirmed to form an orthorhombic structure. Accordingly, the ferroelectric layer denoted by HZO is confirmed to exhibit ferroelectric characteristics.

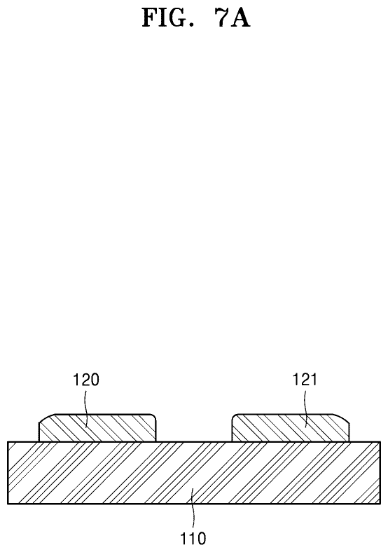

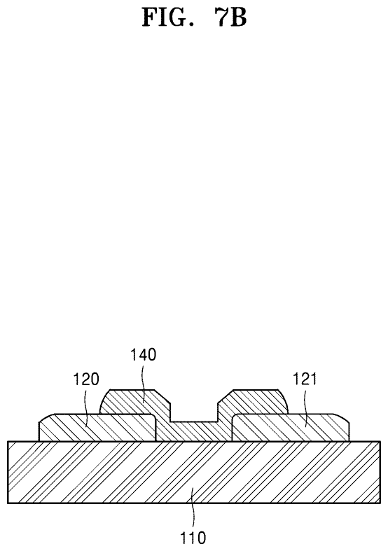

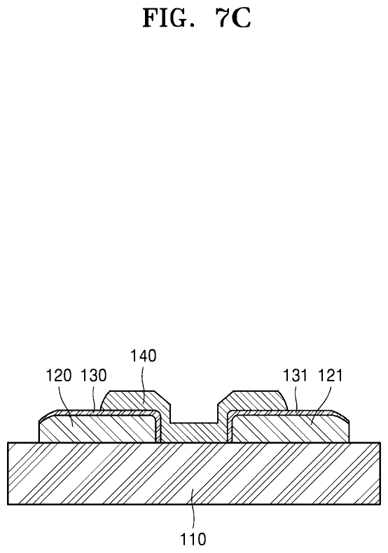

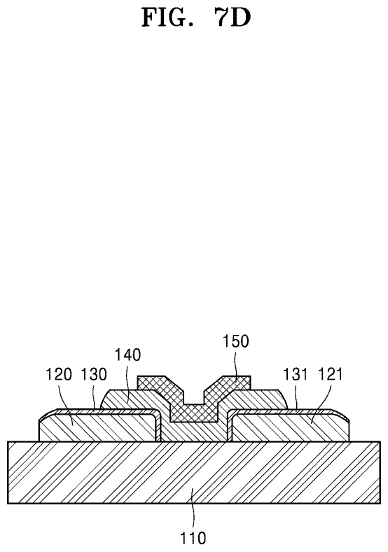

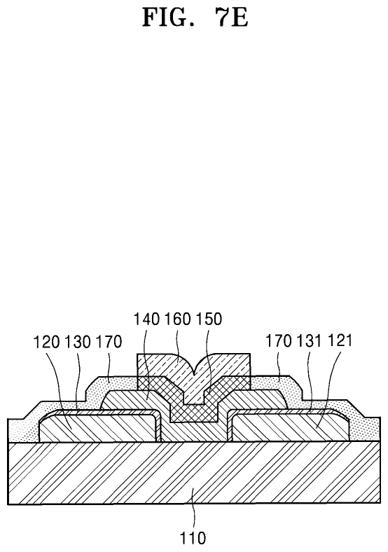

FIGS. 7A to 7E are diagrams illustrating a method of manufacturing a semiconductor device, according to at least one embodiment. The configurations described with reference to FIGS. 7A to 7E may be the same as the configurations described with reference to FIG. 1. In explaining FIGS. 7A to 7E, descriptions redundant with those provided above with reference to FIG. 1 are omitted.

Referring to FIG. 7A, a substrate 110 may be prepared. The substrate 110 may be a silicon substrate. SiO₂ may be formed on the silicon substrate. A source electrode 120 and a drain electrode 121 may be formed on the substrate 110 so as to be apart from each other. The source electrode 120 and the drain electrode 121 may be formed by using, for example, a sputtering process.

Referring to FIG. 7B, a channel layer 140 may be formed to extend between the source electrode 120 and the drain electrode 121 and up to a portion above the source electrode 120 and the drain electrode 121. The channel layer 140 may be formed by using, for example, a plasma enhanced atomic layer deposition (PEALD) process.

Referring to FIG. 7C, a first contact layer 130 may be formed between the source electrode 120 and the channel layer 140 and a second contact layer 131 may be formed between the drain electrode 121 and the channel layer 140.

Referring to FIG. 7D, a ferroelectric layer 150 may be formed on the channel layer 140. The ferroelectric layer 150 may be formed by using, for example, an atomic layer deposition (ALD) process.

Referring to FIG. 7E, a gate electrode 160 may be formed on the ferroelectric layer 150. The gate electrode 160 may be formed by using, for example, a sputtering process. In addition, the semiconductor device 100 may further include a protective layer 170 surrounding the source electrode 120, the drain electrode 121, the channel layer 140, and the ferroelectric layer 150.

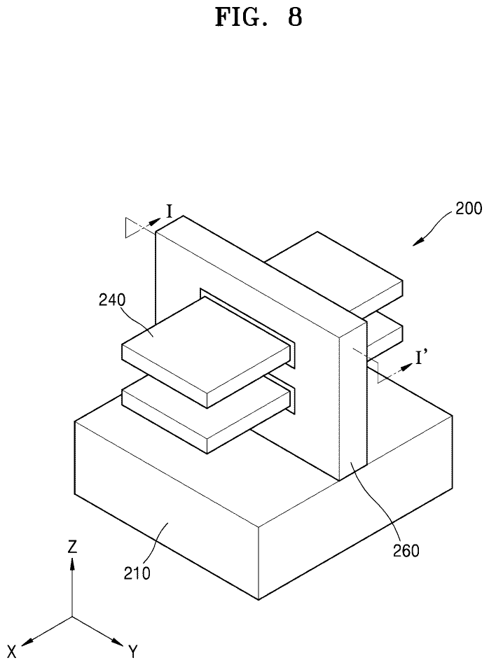

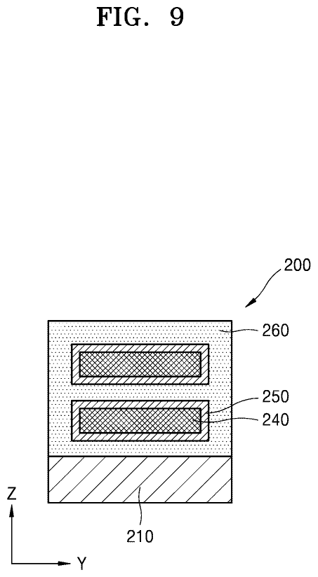

FIG. 8 is a perspective view schematically illustrating a semiconductor device 200 according to another embodiment, and FIG. 9 is a cross-sectional view taken along line I-I′ of FIG. 8.

The cross-section taken along line I-I′ may represent a cross-section cut across a gate electrode 260 (a Y-direction in the drawing) in a direction (a Z-direction in the drawing) perpendicular to a substrate 210. Since the substrate 210 may not have a perfect flat surface, the vertical direction may include an approximately vertical direction as well as a substantially vertical direction.

Referring to FIGS. 8 and 9, a plurality of channel layers 240 may be disposed above the substrate 210 so as to be apart from the substrate 210. FIGS. 8 and 9 illustrate an example in which two channel layers 240 are disposed up and down above the substrate 210. However, this is only an example, and the two channel layers 240 may be disposed to the left and to the right. Additionally, FIGS. 8 and 9 illustrate an example including two channel layers 240, however the example embodiments are not limited thereto, and the plurality of channel layers 240 may include more than two channel layers 240. A source electrode (not shown) and a drain electrode (not shown) may be respectively provided on both sides of each of the two channel layers 240.

The substrate 210 may be an insulating substrate or may be a semiconductor substrate having an insulating material formed on a surface thereof. The semiconductor substrate may include, for example, Si, Ge, SiGe, or a Group III-V semiconductor material. The substrate 210 may be, for example, a silicon substrate having silicon oxide formed on a surface thereof, but the disclosure is not limited thereto.

The channel layer 240 may extend along a direction parallel to the substrate 210. As an example, the channel layer 240 may be provided in the shape of a nanowire extending along one direction or in the shape of a nano sheet extending along one plane. According to at least one embodiment, the channel layer 240 may be provided in plurality. The plurality of channel layers 240 may be apart from each other in the direction (the Z-direction) perpendicular to the substrate 210. In other words, neighboring channel layers 240 may be disposed separately from each other along a first direction (the Z direction). The channel layer 240 may be in direct contact with a source electrode (not shown) and a drain electrode (not shown). However, the disclosure is not limited thereto, and the channel layer 240 may also be connected to the source electrode (not shown) and the drain electrode (not shown) through another medium.

The channel layer 240 may include an oxide semiconductor material. The channel layer 240 may include an oxide semiconductor material including In, Ga, and/or Zn. The channel layer 140 may include IGZO. The channel layer 240 may include an oxide semiconductor material the same as (or substantially similar to) the oxide semiconductor material discussed in relation to the channel layer 140.

A ferroelectric layer 250 may be provided to surround the channel layer 240. The gate electrode 260, the source electrode (not shown), and the drain electrode (not shown) may be insulated from each other by the ferroelectric layer 250. The ferroelectric layer 250 may include a ferroelectric material.

The ferroelectric layer 250 may include a ferroelectric material the same as (or substantially similar to) the ferroelectric material discussed in relation to the ferroelectric layer 150. For example, the ferroelectric layer 250 may include hafnium oxide, zirconium oxide, or hafnium zirconium oxide (HfₓZr₁₋ₓO₂ (0<x<1)). The ferroelectric layer 250 may have an orthorhombic structure. The ferroelectric layer 250 may have an orthorhombic structure at a portion in contact with the gate electrode 260.

The gate electrode 260 may include a conductive material. The gate electrode 260 may include, for example, metal, metal nitride, metal oxide, polysilicon, or the like. As a specific example, the gate electrode 260 may include at least one of W, TiN, TaN, WN, NbN, Mo, Ru, Ir, RuO, IrO, or highly doped polysilicon. The gate electrode 260 may include metal carbide or a two-dimensional conductive material. The gate electrode 260 may include, for example, ITO, Mo, W, Ru, or any combination thereof.

The gate electrode 260 may be disposed above the ferroelectric layer 250 and may be provided to surround the channel layer 240. As an example, the gate electrode 260 may be disposed to surround the entire sides of the channel layer 240. Accordingly, the semiconductor device 200 according to at least one embodiment may be provided as a gate-all-around field effect transistor (GAA FET). The semiconductor device 200 according to at least one embodiment may be provided in a three-dimensional structure such as a GAA FET.

The semiconductor device 200 according to at least one embodiment may use an oxide semiconductor material as the channel layer 240. A memory window of the semiconductor device 200 may be increased by controlling a composition ratio of In:Ga:Zn in the oxide semiconductor material.

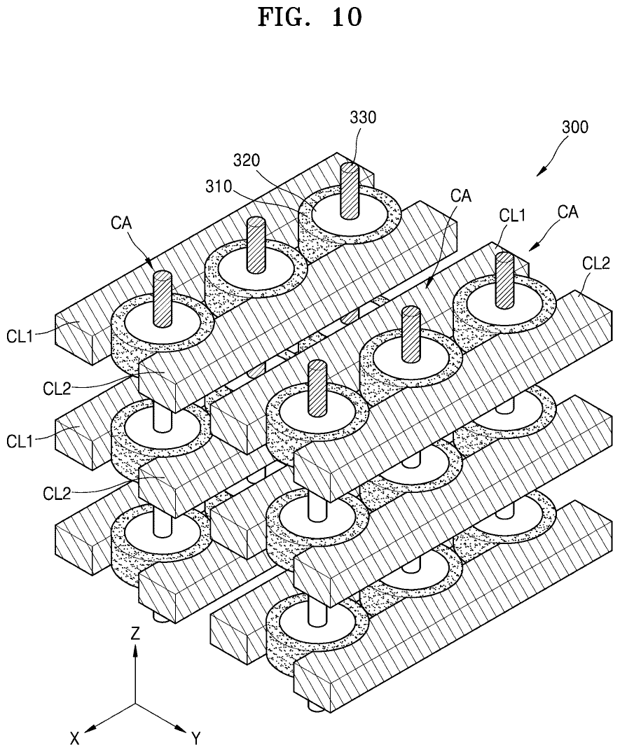

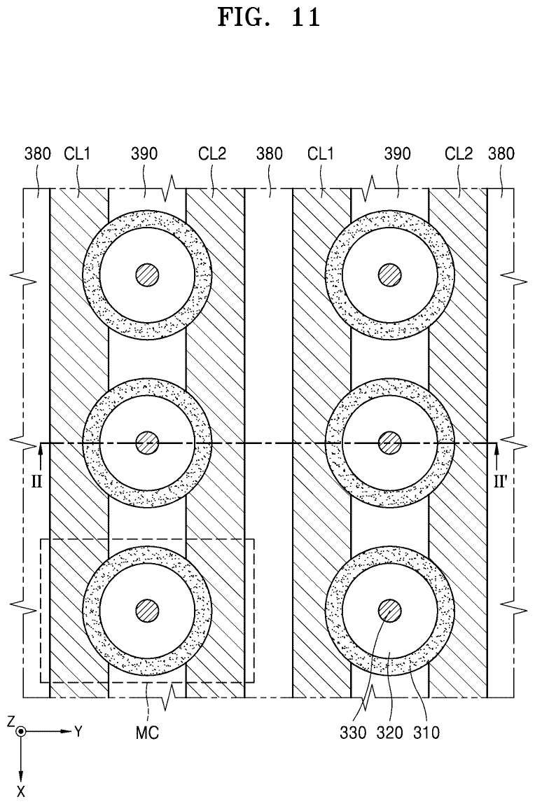

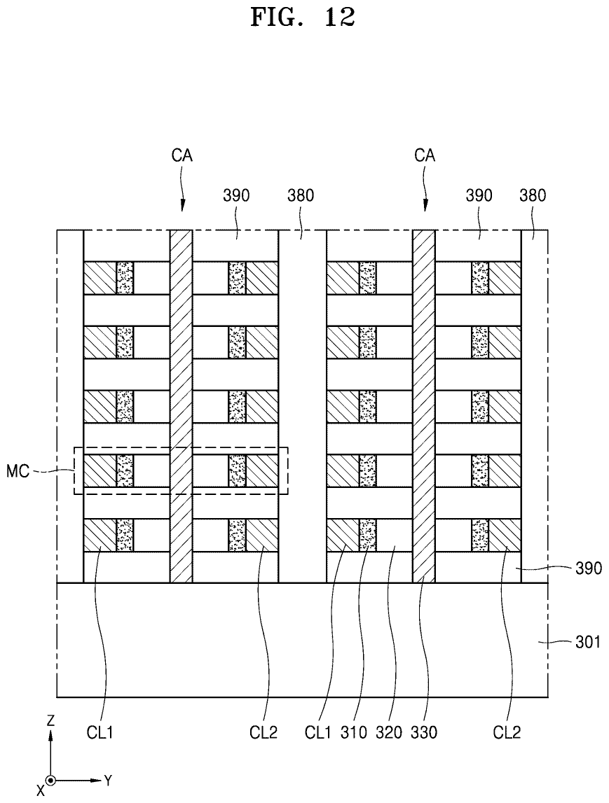

FIG. 10 is a perspective view illustrating a memory device 300 according to at least one embodiment. FIG. 11 is a plan view of the memory device 300 illustrated in FIG. 10. FIG. 12 is a cross-sectional view taken along line II-II′ of FIG. 11. The following description is given focusing on differences from the embodiments described above.

Referring to FIGS. 10 to 12, the memory device 300 may include a plurality of cell arrays CA disposed two-dimensionally on a substrate 301. FIG. 10 illustrates an example in which the cell arrays CA are disposed in the first direction (X-axis direction) and the second direction (Y-axis direction) parallel to the substrate (see 301 of FIG. 12).

Each of the cell arrays CA may be disposed to extend in the direction (Z-axis direction) perpendicular to the substrate 301. Each of the cell arrays CA may include a plurality of memory cells MC apart from each other in the direction (Z-axis direction) perpendicular to the substrate 301.

A first conductive line CL1 and a second conductive line CL2 may be respectively provided on both sides of the memory cells MC apart from each other along the first direction (X-axis direction) parallel to the substrate 301. For example, the first and second conductive lines CL1 and CL2 may be respectively a source electrode and a drain electrode. The first and second conductive lines CL1 and CL2 may be shared by the memory cells MC disposed along the first direction (X-axis direction). A first insulating material 380 may be provided between the cell arrays CA apart from each other in the second direction (Y-axis direction) parallel to the substrate 301. A second insulating material 390 may be provided between the memory cells MC apart from each other in the direction (Z-axis direction) perpendicular to the substrate 301. In addition, the second insulating material 390 may be provided to fill a space between the first and second conductive lines CL1 and CL2 while surrounding the memory cells MC.

The substrate 301 may include various materials. For example, the substrate 301 may include a monocrystalline silicon substrate, a compound semiconductor substrate, or a silicon-on-insulator (SOI) substrate, but the disclosure is not limited thereto. In addition, the substrate 301 may further include, for example, impurity regions formed by doping, electronic elements such as transistors, or peripheral circuits that select and control the memory cells MC storing data, and the like.

Each of the memory cells MC may have a structure in which a gate electrode 330, a ferroelectric layer 320, and a channel layer 310 are sequentially stacked in this stated order in the direction parallel to the substrate 301. The gate electrode 330 may be provided to extend perpendicular to the substrate 301 and may be shared by the memory cells MC constituting each of the cell arrays CA. Each of the ferroelectric layer 320 and the channel layer 310 may be formed in a cylindrical shape surrounding the gate electrode 330.

The gate electrode 330 may include a conductive material. The gate electrode 330 may include, for example, metal, metal nitride, metal oxide, polysilicon, or the like. As a specific example, the gate electrode 330 may include at least one of W, TiN, TaN, WN, NbN, Mo, Ru, Ir, RuO, IrO, or highly doped polysilicon. The gate electrode 330 may include metal carbide or a two-dimensional conductive material. The gate electrode 330 may include, for example, ITO, Mo, W, Ru, or any combination thereof.

The channel layer 310 may include an oxide semiconductor material. The channel layer 310 may include an oxide semiconductor material including In, Ga, and/or Zn. The channel layer 310 may include IGZO. The channel layer 310 may include an oxide semiconductor material the same as (or substantially similar to) the oxide semiconductor material discussed in relation to the channel layer 140 and/or channel layer 240. The channel layer 310 may include a plurality of layers. A composition ratio of In:Ga:Zn in the oxide semiconductor material may be 1:1.3-1.7:1.3-1.7 in at %. The composition ratio of In:Ga:Zn in the oxide semiconductor material may be, for example, 2:3:3 in at %.

The ferroelectric layer 320 may be provided between the gate electrode 330 and the channel layer 310. The ferroelectric layer 320 may include a ferroelectric material. The ferroelectric material of the ferroelectric layer 320 may be the same as (or substantially similar to) the ferroelectric material discussed in relation to the ferroelectric layer 150 and/or ferroelectric layer 250. For example, the ferroelectric layer 320 may include at least one of hafnium oxide, zirconium oxide, or hafnium zirconium oxide (HfₓZr₁₋ₓO₂ (0<x<1)). The ferroelectric layer 320 may further include a dopant. The dopant may include at least one of La, Y, Gd, Si, Al, Mg, Sr, or Ba.

As described above, the memory device 300 according to at least one embodiment may use an oxide semiconductor material as the channel layer 310. A memory window of the memory device 300 may be increased by controlling a composition ratio of In:Ga:Zn in the oxide semiconductor material.

A case where the ferroelectric layer 320 and the channel layer 310 sequentially surrounding the gate electrode 330 are provided separately for each memory cell MC in the direction (Z-axis direction) perpendicular to the substrate 301 has been described with reference to FIGS. 10 to 12. However, the present embodiment is not limited thereto, and both the ferroelectric layer 320 and the channel layer 310 may be commonly provided for the memory cells MC in the direction (Z-axis direction) perpendicular to the substrate 301. In addition, a portion of the ferroelectric layer 320 and the channel layer 310 may be provided separately for each memory cell MC in the direction (Z-axis direction) perpendicular to the substrate 301.

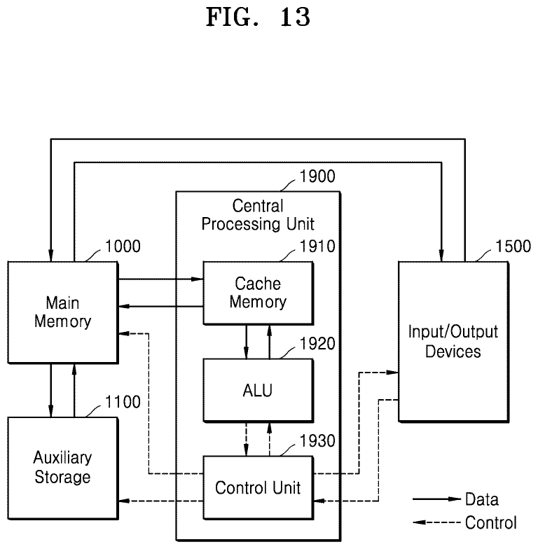

FIG. 13 is a conceptual diagram schematically illustrating a device architecture applicable to an electronic device, according to embodiments.

Referring to FIG. 13, a cache memory 1910, an arithmetic logic unit (ALU) 1920, and a control unit 1930 may constitute a central processing unit (CPU) 1900. The cache memory 1910 may include a static random access memory (SRAM). Apart from the CPU 1900, a main memory (or a memory system) 1000 and an auxiliary storage 1100 may be provided. The main memory 1000 may include a dynamic random access memory (DRAM) and the auxiliary storage 1100 may include the semiconductor devices 100, 101, and/or 200; and/or may include the memory device 300. In some cases, the device architecture may be implemented in a form in which computing unit elements and memory unit elements are adjacent to each other on a single chip, without distinction of sub-units.

The semiconductor devices 100, 101, and 200 or the memory device 300 according to the aforementioned embodiments may be implemented as chip-type memory blocks and used as a neuromorphic computing platform, or may be used to construct a neural network.

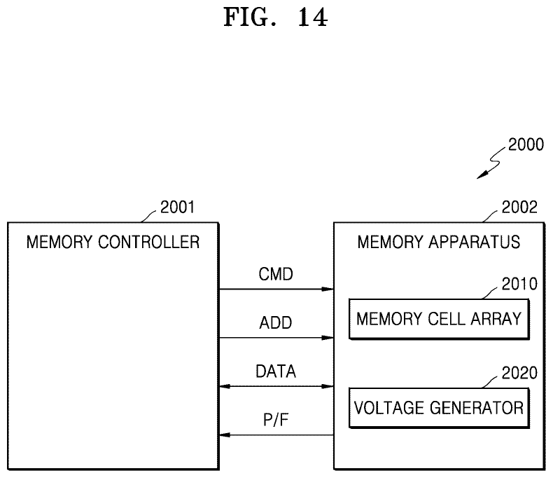

FIG. 14 is a block diagram of a memory system 2000 according to at least one embodiment.

Referring to FIG. 14, the memory system 2000 may include a memory controller 2001 and a memory apparatus 2002. The memory controller 2001 may perform a control operation on the memory apparatus 2002. For example, the memory controller 2001 may provide, to the memory apparatus 2002, an address ADD and a command CMD for performing program (or write), read, and/or erase operations on the memory apparatus 2002. In addition, data for the program operation and the read operation may be transmitted between the memory controller 2001 and the memory apparatus 2002.

The memory apparatus 2002 may include a memory cell array 2010 and a voltage generator 2020. The memory cell array 2010 may include a plurality of memory cells and may include the semiconductor devices 100, 101, and/or 200; and/or may include the memory device 300 according to the aforementioned embodiments.

The memory controller 2001 may include processing circuitry such as hardware including a logic circuit, a hardware/software combination such as processor execution software, or any combination thereof. More specifically, the processing circuitry may be, for example, a CPU, an ALU, a digital signal processor, a microcomputer, a field programmable gate array (FPGA), a system-on-chip (SoC), a programmable logic unit, a microprocessor, an application-specific integrated circuit (ASIC), or the like, but the disclosure is not limited thereto. The memory controller 2001 may be configured to operate in response to a request from a host (not shown) and may be configured to access the memory apparatus 2002 and control the control operation (e.g., the write/read operation) so that the memory controller 2001 is converted to a special-purpose controller. The memory controller 2001 may generate an address ADD and a command CMD for performing the program/read/erase operations on the memory cell array 2010. In addition, in response to a command from the memory controller 2001, the voltage generator 2020 (e.g., power circuitry) may generate and/or provide a voltage control signal for controlling a voltage level of a word line for programming data to the memory cell array 2010 or reading data from the memory cell array 2010.

In addition, the memory controller 2001 may perform a determination operation on data read from the memory apparatus 2002. For example, the number of on-cells and/or the number of off-cells may be determined from data read from the memory cell. The memory apparatus 2002 may provide a pass/fail signal P/F to the memory controller 2001 according to a reading result of the read data. The memory controller 2001 may control the write/read operations of the memory cell array 2010 by referring to the pass/fail signal P/F.

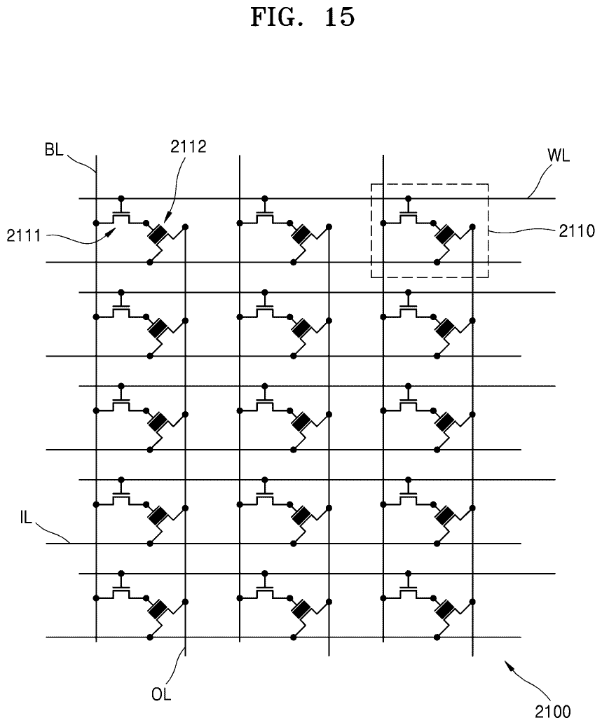

FIG. 15 is a schematic circuit diagram of a neural network device 2100 according to at least one embodiment.

Referring to FIG. 15, the neural network device 2100 according to at least one embodiment may include an array of a plurality of synaptic elements 2110 disposed two-dimensionally. Each of the synaptic elements 2110 may include an access transistor 2111 and a ferroelectric field effect transistor 2112. The ferroelectric field effect transistor 2112 may be one of the semiconductor devices 100 and 101 described above. The access transistor 2111 may act as a selection element that turns on/off the synaptic element 2110.

The neural network device 2100 may also include a plurality of word lines WL, a plurality of bit lines BL, a plurality of input lines IL, and a plurality of output lines OL. The access transistor 2111 may have a gate electrically connected to one of the word lines WL, a source electrically connected to one of the bit lines BL, and a drain connected to a gate of the ferroelectric field effect transistor 2112. In addition, the ferroelectric field effect transistor 2112 may have a source electrically connected to one of the input lines IL and a drain electrically connected to one of the output lines OL.

During a learning operation of the neural network device 2100, the access transistor 2111 may be individually turned on through the individual word line WL, so that a program pulse may be applied to the gate of the ferroelectric field effect transistor 2112 through the bit line BL. A signal of training data may be applied through the input line IL. Through this process, a weight may be stored in each of the ferroelectric field effect transistor 2112.

During an inference operation of the neural network device 2100, all the access transistors 2111 may be turned on through the entire word lines WL and a read voltage (Vread) may be applied through the bit lines BL. Currents from the synaptic elements 2110 respectively connected in parallel to the output lines OL may be added and then flow to the output lines OL. Output circuits may be respectively connected to the output lines OL and may convert the currents flowing through the output lines OL into digital signals.

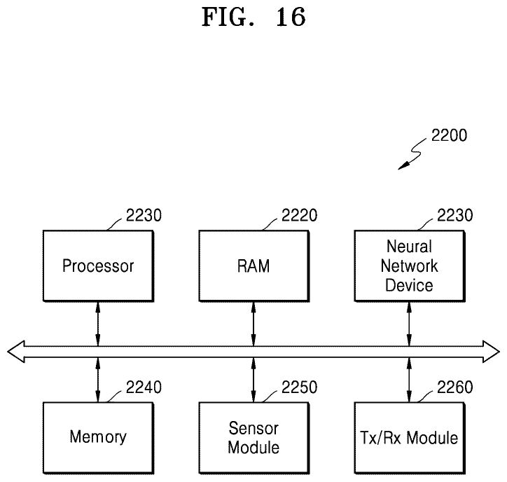

FIG. 16 is a block diagram schematically illustrating an example of a configuration of an electronic device 2200 including a neural network device.

Referring to FIG. 16, the electronic device 2200 may extract valid information by analyzing input data in real time based on a neural network and may determine a situation based on the extracted information or may control elements of a device on which the electronic device 2200 is mounted. For example, the electronic device 2200 may be applied to a drone, a robot device such as an advanced drivers assistance system (ADAS), a smart television (TV), a smartphone, a medical device, a mobile device, an image display device, a measuring device, an Internet of things (IoT) device, etc., and may be mounted on at least one of various types of devices.

The electronic device 2200 may include a processor 2210, a random access memory (RAM) 2220, a neural network device 2230, a memory 2240, a sensor module 2250, and a communication module 2260. At least one of the processor 2210, the random access memory (RAM) 2220, the neural network device 2230, the memory 2240, the sensor module 2250, and the communication module 2260 may include the semiconductor devices 100, 101, and/or 200; the memory device 300; and/or the neural network device 2100 according to the aforementioned embodiments. The electronic device 2200 may further include an input/output module, a security module, a power controller, and the like. Some hardware components of the electronic device 2200 may be mounted on at least one semiconductor chip.

The processor 2210 may control the overall operation of the electronic device 2200. The processor 2210 may include one processor core (single core) or a plurality of processor cores (multi-core). The processor 2210 may process or execute programs and/or data stored in the memory 2240. In some embodiments, the processor 2210 may control the functions of the neural network device 2230 by executing the programs stored in the memory 2240. The processor 2210 may be implemented as a CPU, a graphics processing unit (GPU), an application processor (AP), or the like.

The RAM 2220 may temporarily store programs, data, or instructions. For example, the programs and/or the data stored in the memory 2240 may be temporarily stored in the RAM 2220 according to a control or booting code of the processor 2210. The RAM 2220 may be implemented as memory such as DRAM or SRAM.

The neural network device 2230 may perform a neural network operation based on received input data and generate an information signal based on a result of performing the neural network operation. The neural network may include a convolutional neural network (CNN), a recurrent neural network (RNN), a fully connected neural network (FNN), a long short-term memory (LSTM), a stacked neural network (SNN), a state-space dynamic neural network (SSDNN), a deep belief network (DBN), or a restricted Boltzmann machine (RBM), but the disclosure is not limited thereto. The neural network device 2230 may be a neural network-specific hardware accelerator itself or a device including the same. The neural network device 2230 may perform not only neural network operations but also read or write operations. The neural network device 2230 may correspond to the neural network device 2100 according to the embodiment illustrated in FIG. 15.

The information signal may include one of various types of recognition signals, such as a voice recognition signal, an object recognition signal, an image recognition signal, or a biometric information recognition signal. For example, the neural network device 2230 may receive frame data included in a video stream as input data and generate, from the frame data, a recognition signal for an object included in an image represented by the frame data. However, the disclosure is not limited thereto, and the neural network device 2230 may receive various types of input data according to a type or a function of a device on which the electronic device 2200 is mounted and may generate a recognition signal according to the input data.

The neural network device 2230 may perform a machine learning model, such as linear regression, logistic regression, statistical clustering, Bayesian classification, decision trees, principal component analysis, and/or expert systems, and/or ensemble techniques, such as random forests. The machine learning model may be used to provide various services, such as an image classification service, a user authentication service based on biometric information or biometric data, an ADAS, a voice assistant service, or an automatic speech recognition (ASR) service.

The memory 2240 is a storage for storing data and may store an operating system (OS), various programs, and various data. In at least one embodiment, the memory 2240 may store intermediate results generated during the computational process of the neural network device 2230.

The memory 2240 may be DRAM, but the disclosure is not limited thereto. The memory 2240 may include at least one of volatile memory or non-volatile memory. The non-volatile memory may include read only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), or ferroelectric RAM (FRAM). The volatile memory may include DRAM, SRAM, or synchronous DRAM (SDRAM). In at least one embodiment, the memory 2240 may include at least one of hard disk drive (HDD), solid state drive (SSD), compact flash (CF), secure digital (SD), micro secure digital (micro-SD), mini secure digital (mini-SD), or memory stick.

The sensor module 2250 may collect information about the surroundings of the device on which the electronic device 2200 is mounted. The sensor module 2250 may sense or receive signals (e.g., video signals, audio signals, magnetic signals, bio-signals, touch signals, etc.) from the outside of the electronic device 2200 and convert the sensed or received signals into data. To this end, the sensor module 2250 may include at least one of various types of sensing devices, such as a microphone, an imaging device, an image sensor, a light detection and ranging (LiDAR) sensor, an ultrasonic sensor, an infrared sensor, a biosensor, or a touch sensor.

The sensor module 2250 may provide the converted data to the neural network device 2230 as input data. For example, the sensor module 2250 may include an image sensor, may capture an image of an external environment of the electronic device 2200 to generate a video stream, and may sequentially provide consecutive data frames of the video stream to the neural network device 2230 as input data. However, the disclosure is not limited thereto, and the sensor module 2250 may provide various types of data to the neural network device 2230.

The communication module 2260 may include various wired or wireless interfaces enabling communication with external devices. For example, the communication module 2260 may include a communication interface connectable to a wired local area network (LAN), a wireless local area network (WLAN) such as Wireless Fidelity (Wi-Fi), a wireless personal area network (WPAN) such as Bluetooth, a wireless universal serial bus (USB), ZigBee, near field communication (NFC), radio-frequency identification (RFID), power line communication (PLC), or a mobile cellular network such as 3rd generation (3G), 4th generation (4G), fifth generation (5G), or long term evolution (LTE).

In the semiconductor device and the memory device including the same according to the disclosure, a high memory window may be achieved by controlling a composition ratio of In:Ga:Zn in an oxide semiconductor material forming a channel layer, and thus, the reliability of data storage and retrieval may be improved. The semiconductor device and the memory device including the same have been described with reference to the embodiments illustrated in the drawings, but this is only an example. It will be understood by those of ordinary skill in the art that various modifications and equivalents may be made thereto. Therefore, the disclosed embodiments should be considered in an illustrative sense rather than a restrictive sense. The scope of the disclosure is indicated in the claims rather than the foregoing description, and all differences within the scope equivalent thereto should be construed as falling within the disclosure.

In the semiconductor device and the memory device including the same according to the embodiments, a high memory window may be achieved by controlling a composition ratio of In:Ga:Zn in an oxide semiconductor material forming a channel layer, and thus, the reliability of data storage and retrieval may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer comprising an oxide semiconductor material comprising indium (In), gallium (Ga), and zinc (Zn);
a ferroelectric layer on the channel layer; and
a gate electrode on the ferroelectric layer such that the ferroelectric layer insulates the channel layer from the gate electrode,
wherein a composition ratio of In:Ga:Zn in the oxide semiconductor material is 1:1.3-1.7:1.3-1.7 in atomic percent (at %).

2. The semiconductor device of claim 1, wherein the gate electrode comprises indium tin oxide (ITO), molybdenum (Mo), tungsten (W), ruthenium (Ru), or a combination thereof.

3. The semiconductor device of claim 1, wherein the ferroelectric layer comprises a non-centrosymmetric crystal structure.

4. The semiconductor device of claim 3, wherein the ferroelectric layer comprises an orthorhombic crystal structure at a portion in contact with the gate electrode.

5. The semiconductor device of claim 1, wherein the ferroelectric layer comprises at least one of hafnium oxide, zirconium oxide, or hafnium zirconium oxide (HfₓZr₁₋ₓO₂ (0<x<1)).

6. The semiconductor device of claim 1, further comprising:
a source electrode and a drain electrode spaced apart from each other with the channel layer therebetween.

7. The semiconductor device of claim 6, further comprising:
at least one of a first contact layer between the source electrode and the channel layer or a second contact layer between the drain electrode and the channel layer.

8. The semiconductor device of claim 7, wherein the first contact layer and the second contact layer each comprise an In-containing oxide.

9. The semiconductor device of claim 8, wherein each of the first contact layer and the second contact layer comprises ITO or indium oxide.

10. The semiconductor device of claim 1, wherein the composition ratio of In:Ga:Zn in the oxide semiconductor material is 2:3:3 in at %.

11. An electronic device comprising the semiconductor device of claim 1.

12. A memory device comprising:
a plurality of memory cells disposed vertically on a substrate, each of the plurality of memory cells comprising
a ferroelectric layer on a gate electrode, the gate electrode extending in a direction perpendicular to the substrate, and
a channel layer on the ferroelectric layer such that the ferroelectric layer insulates the channel layer from the gate electrode, the channel layer comprising an oxide semiconductor material comprising indium (In), gallium (Ga), and zinc (Zn),
wherein a composition ratio of In:Ga:Zn in the oxide semiconductor material is 1:1.3-1.7:1.3-1.7 in atomic percent (at %).

13. The memory device of claim 12, wherein the gate electrode comprises indium tin oxide (ITO), molybdenum (Mo), tungsten (W), ruthenium (Ru), or a combination thereof.

14. The memory device of claim 12, wherein the ferroelectric layer comprises at least one of hafnium oxide, zirconium oxide, or hafnium zirconium oxide (HfₓZr₁₋ₓO₂ (0<x<1)).

15. The memory device of claim 12, further comprising:
a source electrode and a drain electrode on respective sides of each of the plurality of memory cells.

16. The memory device of claim 12, wherein the gate electrode is shared by the plurality of memory cells.

17. The memory device of claim 12, wherein the composition ratio of In:Ga:Zn in the oxide semiconductor material is 2:3:3 in at %.
